(19) United States
(12) Patent Application Publication
(10) Pub. No.: US 2026/0100215 A1
(43) Pub. Date: Apr. 9, 2026

(54) REFRESH CIRCUIT AND MEMORY

(71) Applicant: CXMT Corporation, Hefei City (CN)

(72) Inventor: Jianpeng SUN, Hefei City (CN)

(73) Assignee: CXMT Corporation, Hefei City (CN)

(21) Appl. No.: 19/383,634

(22) Filed: Nov. 8, 2025

Related U.S. Application Data
(63) Continuation of application No. PCT/CN2024/085227, filed on Apr. 1, 2024.

(30) Foreign Application Priority Data
Jun. 6, 2023 (CN) 202310666924.4

(51) Int. Cl. G11C 11/406; G11C 11/4076

(52) U.S. Cl. CPC G11C 11/40615; G11C 11/40622; G11C 11/4076

(57) ABSTRACT

The present disclosure provides a refresh circuit and a memory. A feedback control circuit is configured to: receive a pump delay signal and a blast-radius configuration, generate a pump trigger signal based on the pump delay signal, and terminate the generation of the pump trigger signal in the case that a quantity of pump signals expected to be generated meets a requirement of the blast-radius configuration. The pump signal is generated in the case that a refresh signal or the pump trigger signal is in an enabled state. A rising edge of the pump delay signal is delayed relative to a rising edge of the pump signal by a first preset duration.

### CROSS-REFERENCE TO RELATED APPLICATIONS

The present disclosure is a continuation application of International Application No. PCT/CN2024/085227 filed on Apr. 1, 2024, which claims priority to Chinese Patent Application No. 202310666924.4 filed on Jun. 6, 2023. The disclosures of the above-referenced applications are hereby incorporated by reference in their entirety.

### BACKGROUND

Memories such as a dynamic random access memory (dynamic random access memory, DRAM) can store data by storing charges in a capacitor of a memory cell. Since charges stored in a capacitor leak over time, a dynamic random access memory needs to periodically perform refreshing. In practice, data is periodically rewritten into a capacitor. As memories are scaling down through manufacturing processes, there is smaller spacing between word lines, and the voltage distribution within one word line may cause an increase of charge in a memory cell corresponding to an adjacent word line. When one word line is intensively accessed, the row hammer effect in which data stored in a memory cell corresponding to an adjacent word line is subject to voltage leakage (data loss) due to repeated activation of the word line may occur.

### SUMMARY

The present disclosure relates to the field of semiconductors, and in particular, to a refresh circuit and a memory.

In a first aspect, an embodiment of the present disclosure provides a refresh circuit. The refresh circuit includes: a feedback control circuit, configured to: receive a pump delay signal and a blast-radius configuration; generate a pump trigger signal based on the pump delay signal, the pump trigger signal being used to generate a pump signal, and each pump signal having a corresponding pump delay signal; and terminate the generation of the pump trigger signal in a case that a quantity of pump signals expected to be generated meets a requirement of the blast-radius configuration, where the pump signal is used to perform a refresh operation; and a first operation circuit, configured to: receive a refresh signal and the pump trigger signal, perform a logic operation on the refresh signal and the pump trigger signal, and generate the pump signal in a case that the refresh signal or the pump trigger signal is in an enabled state, where each pump signal is used to perform one refresh operation; and a rising edge of the pump delay signal is delayed relative to a rising edge of the pump signal by a first preset duration.

In a second aspect, an embodiment of the present disclosure provides a memory. The memory includes: a plurality of memory banks and a refresh management circuit. The refresh management circuit is coupled to the plurality of memory banks and includes the refresh circuit provided in the embodiments of the present disclosure.

### BRIEF DESCRIPTION OF DRAWINGS

FIG. 1A is a schematic diagram of a configuration manner for a blast-radius configuration in a register according to an embodiment of the present disclosure;

FIG. 1B is a schematic diagram of different types of blast-radius configurations according to an embodiment of the present disclosure;

FIG. 2 is a schematic diagram of a composition structure of a refresh circuit according to an embodiment of the present disclosure;

FIG. 3 is a schematic diagram of a composition structure of yet another refresh circuit according to an embodiment of the present disclosure;

FIG. 4 is a schematic diagram of a composition structure of a feedback control circuit in a refresh circuit according to an embodiment of the present disclosure;

FIG. 5A is a first schematic diagram of a partial composition structure of an enable circuit in a feedback control circuit according to an embodiment of the present disclosure;

FIG. 5B is a second schematic diagram of a partial composition structure of an enable circuit in a feedback control circuit according to an embodiment of the present disclosure;

FIG. 5C is a third schematic diagram of a partial composition structure of an enable circuit in a feedback control circuit according to an embodiment of the present disclosure;

FIG. 5D is a fourth schematic diagram of a partial composition structure of an enable circuit in a feedback control circuit according to an embodiment of the present disclosure;

FIG. 6 is a schematic diagram of a composition structure of a first operation circuit in a refresh circuit according to an embodiment of the present disclosure;

FIG. 7 is a schematic diagram of a composition structure of another refresh circuit according to an embodiment of the present disclosure;

FIG. 8 is a schematic diagram of a composition structure of a boundary circuit in a refresh circuit according to an embodiment of the present disclosure;

FIG. 9A is a first schematic diagram of a partial composition structure of a refresh-off circuit in a boundary circuit according to an embodiment of the present disclosure;

FIG. 9B is a second schematic diagram of a partial composition structure of a refresh-off circuit in a boundary circuit according to an embodiment of the present disclosure;

FIG. 9C is a third schematic diagram of a partial composition structure of a refresh-off circuit in a boundary circuit according to an embodiment of the present disclosure;

FIG. 10A is a schematic diagram of a time sequence of main signals in a working refresh circuit according to an embodiment of the present disclosure;

FIG. 10B is a schematic diagram of a time sequence in a process of generating the first pump signal and the first pump trigger signal in a working refresh circuit according to an embodiment of the present disclosure; and

FIG. 11 is a schematic diagram of a composition structure of a memory according to an embodiment of the present disclosure.

### DESCRIPTION OF EMBODIMENTS

The technical solutions in embodiments of the present disclosure will be clearly and completely described below with reference to the drawings in the embodiments of the present disclosure. It can be understood that the specific embodiments described herein are merely illustrative of a related application and are not intended to limit the present application. In addition, it should be noted that for the convenience of description, only the portions relevant to the related applications are shown in the drawings.

Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure.

In the following description, reference is made to “some embodiments” which describe subsets of all possible embodiments, but it can be understood that “some embodiments” may be the same subset or different subsets of all possible embodiments, and may be combined with each other without conflict.

It should be noted that the terms “first\second” referred to in the embodiments of the present disclosure are merely used to distinguish similar objects and do not represent a specific ordering for the objects. It can be understood that “first\second” may be subjected to interchange of a specific order or sequence if permitted, such that the embodiments of the present disclosure described herein can be implemented in an order other than that shown or described herein.

To have a more detailed understanding of the characteristics and technical content of the embodiments of the present disclosure, the implementation of the embodiments of the present disclosure is described in detail in combination with the drawings. The attached drawings are for the purposes of reference and explanation only and are not used to limit the embodiments of the present disclosure.

The memory according to the embodiments of the present disclosure includes, but is not limited to, a dynamic random access memory. A specific type of the memory according to the embodiments of the present disclosure will be described in detail below, and a dynamic random access memory is merely used as an example for describing and analyzing the row hammer effect.

A memory cell of a dynamic random access memory is essentially a capacitor that stores charges that may leak in reading, writing, and refreshing processes, and the reading process is destructive in itself. Based on this, the value of the capacitor needs to be refreshed immediately after a read operation, or if a memory cell is not accessed for a long time, the value needs to be refreshed at a pre-specified rate.

Data stored in the memory cell depends on the charge in the capacitor, while the charge is prone to being affected between refresh cycles. A drifting electron may migrate into or out of the memory cell, which changes the charge in the memory cell. If too many accesses occur within a short time, enough charge changes may accumulate to change the sensing state of a storage value. This is when a row hammer occurs. With a specific cumulative effect, before refresh occurs, repeated minute bursts of these erroneous electrons (drifting electrons) can change data stored in an adjacent row. In practice, with the trend of miniaturization, not merely an adjacent row may be a victim row (a row with a changed storage value). As the distance between adjacent word lines decreases, even nearby rows (two or more rows apart) may also be affected.

The row hammer effect can be mitigated or avoided by improving a refresh rate or additionally refreshing rows near an attacked row. As improving a refresh rate leads to a lower data bandwidth and higher power consumption of a memory, the row hammer effect is to be mitigated or avoided by additionally refreshing rows near an attacked row.

In the embodiments of the present disclosure, during row hammer refresh, a row physically near an attacked row is to be refreshed, and a specific row to be refreshed may depend on a radius parameter specified by a blast-radius configuration (blast-radius configuration, BRC). That is, different refreshing times with different pumps are achieved based on different blast-radius configurations.

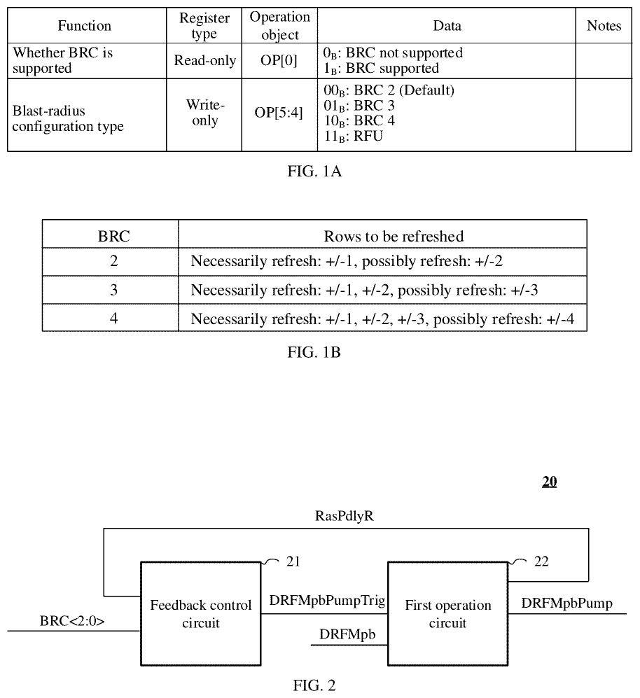

FIG. 1A is a schematic diagram of a configuration manner for a blast-radius configuration in a register according to an embodiment of the present disclosure; and FIG. 1B is a schematic diagram of different types of blast-radius configurations according to an embodiment of the present disclosure.

In some embodiments, the blast-radius configuration BRC is an optional function of DRAMs. As shown in FIG. 1A, whether the blast-radius configuration BRC is supported by a directed refresh management (directed refresh management, DRFM) module may be defined by a mode register (mode register, MR), for example, by using a one-bit parameter OP [0] in MR75. Illustratively, OP [0] being “0” indicates that the blast-radius configuration BRC is not supported, and OP [0] being “1” indicates that the blast-radius configuration BRC is supported. A value of the blast-radius configuration BRC may be defined by a mode register, for example, by using two-bit OP [5:4] in MR75. Illustratively, the value of the blast-radius configuration BRC may include two, three, four, etc., and the value of the blast-radius configuration BRC characterizes a maximum refresh range of the directed refresh management module. A higher value of the blast-radius configuration BRC indicates a larger maximum refresh range. The value of the blast-radius configuration BRC is equal to a refresh radius of the maximum refresh range.

In some embodiments, to reduce power consumption, different refresh rates may be set for victim rows at different distances from a hammered row. As shown in FIG. 1B, in the case that the value of the blast-radius configuration BRC is two, the directed refresh management module necessarily refreshes an adjacent row of a hammered row, that is, ±1 row, and refreshes a row farthest from the hammered row within the maximum refresh range with a specific probability, that is, a row that is one word line apart from the hammered row, that is, ±2 rows; in the case that the value of the blast-radius configuration BRC is three, the DRFM necessarily refreshes ±1 row and ±2 rows, and refreshes a row farthest from the hammered row within the maximum refresh range with a specific probability, that is, the row that is two word lines apart from the hammered row, that is, ±3 rows; and in the case that the value of the blast-radius configuration BRC is equal to four, the refresh goes on by the same logic, which is not described herein. It should be noted that, setting different refresh rates for victim rows at different distances from the hammered row is merely optional. In practice, refresh rates for the different victim rows may be the same within the maximum refresh range characterized by the value of the blast-radius configuration BRC.

The embodiments of the present disclosure provide a refresh circuit. The refresh circuit can achieve different refreshing times with different pumps based on different blast-radius configurations BRC.

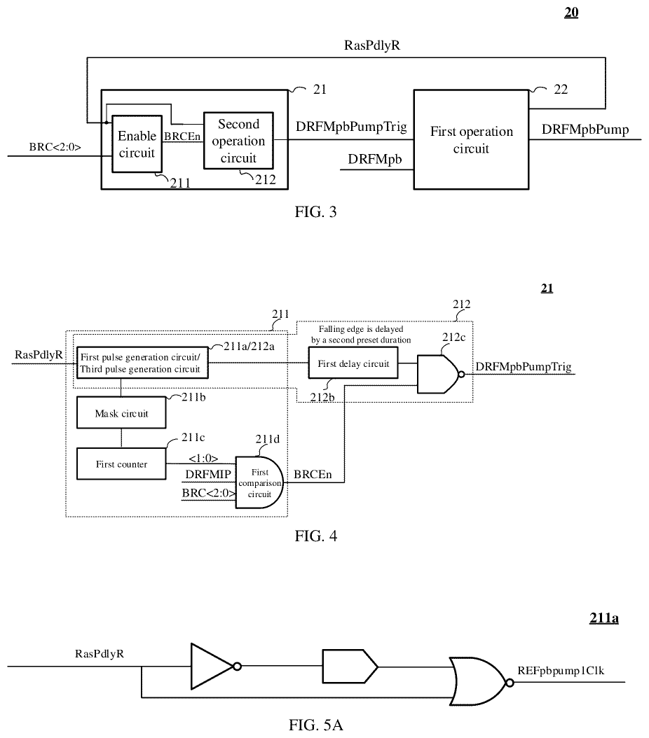

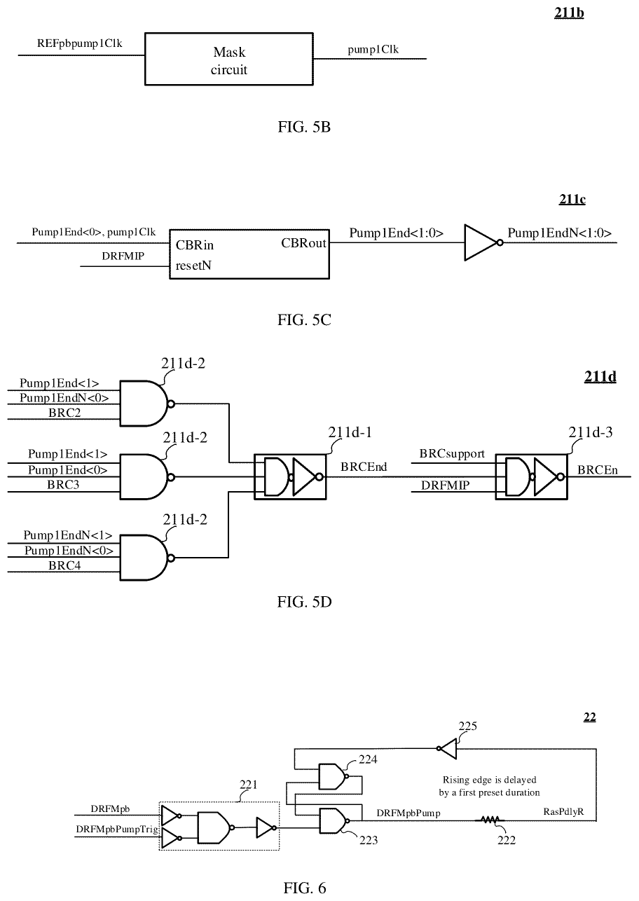

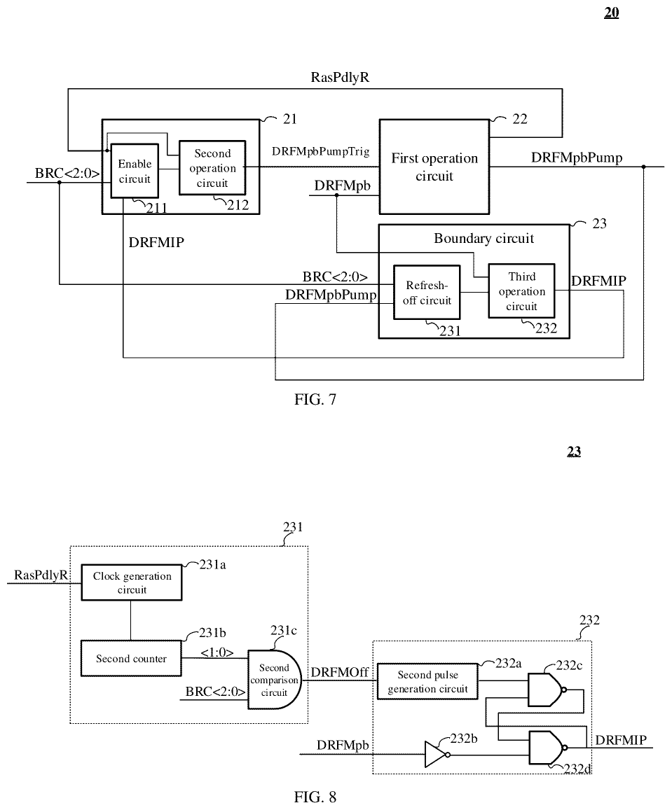

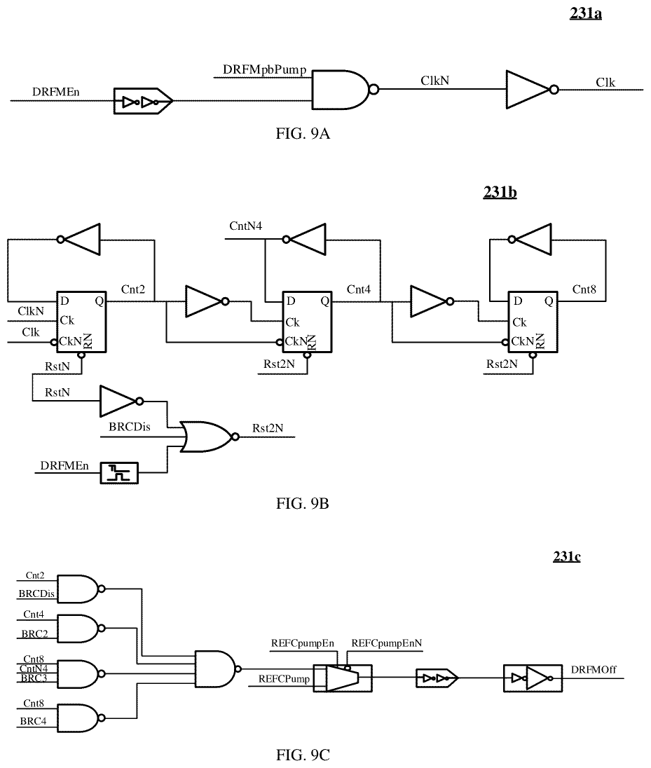

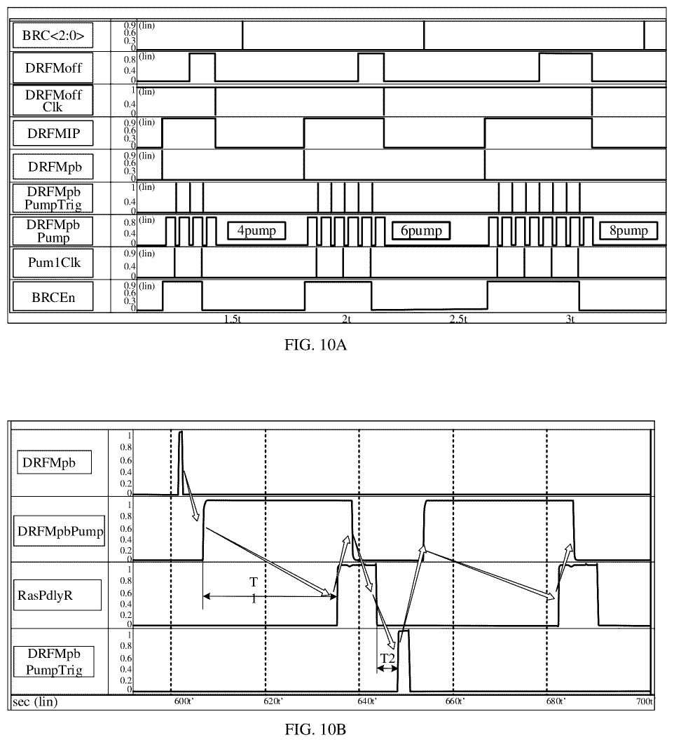

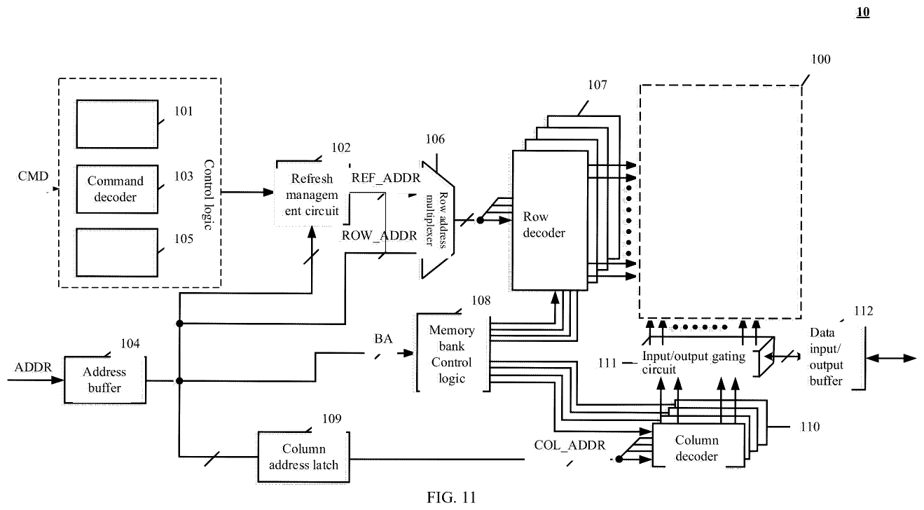

FIG. 2 is a schematic diagram of a composition structure of a refresh circuit according to an embodiment of the present disclosure; FIG. 3 is a schematic diagram of a composition structure of yet another refresh circuit according to an embodiment of the present disclosure; FIG. 4 is a schematic diagram of a composition structure of a feedback control circuit in a refresh circuit according to an embodiment of the present disclosure; FIG. 5A to FIG. 5D are schematic diagrams of a composition structure of an enable circuit in a feedback control circuit according to embodiments of the present disclosure; FIG. 6 is a schematic diagram of a composition structure of a first operation circuit in a refresh circuit according to an embodiment of the present disclosure; FIG. 7 is a schematic diagram of a composition structure of another refresh circuit according to an embodiment of the present disclosure; FIG. 8 is a schematic diagram of a composition structure of a boundary circuit in a refresh circuit according to an embodiment of the present disclosure; FIG. 9A to FIG. 9C are schematic diagrams of a composition structure of a refresh-off circuit in a boundary circuit according to embodiments of the present disclosure; FIG. 10A is a schematic diagram of a time sequence of main signals in a working refresh circuit according to an embodiment of the present disclosure; and FIG. 10B is a schematic diagram of a time sequence in a process of generating the first pump signal and the first pump trigger signal in a working refresh circuit according to an embodiment of the present disclosure.

The following describes the composition and the operating principle of the refresh circuit provided in the embodiments of the present disclosure in detail with reference to FIG. 2 to FIG. 10B.

As shown in FIG. 2, the refresh circuit 20 includes:
a feedback control circuit 21, configured to: receive a pump delay signal and a blast-radius configuration; generate a pump trigger signal based on the pump delay signal, where the pump trigger signal is used to generate a pump signal, and each pump signal has a corresponding pump delay signal; and terminate the generation of the pump trigger signal in the case that a quantity of pump signals expected to be generated meets a requirement of the blast-radius configuration; and the pump signal is used to perform a refresh operation; and
a first operation circuit 22, configured to: receive a refresh signal and the pump trigger signal, perform a logic operation on the refresh signal and the pump trigger signal, and generate the pump signal in the case that the refresh signal or the pump trigger signal is in an enabled state, where each pump signal is used to perform one refresh operation, and a rising edge of the pump delay signal is delayed relative to a rising edge of the pump signal by a first preset duration.

It should be noted that, the refresh circuit 20 provided in the embodiments of the present disclosure may be applied to various memory refresh scenarios, for example, to a refresh management circuit in a DRAM for row hammer refresh.

It should be noted that, the refresh circuit 20 provided in the embodiments of the present disclosure may generate a corresponding quantity of pump signals based on a configured value of the blast-radius configuration BRC, that is, generate the same quantity of pump signals based on a quantity of rows required to be refreshed indicated by the configured value of the blast-radius configuration BRC. For example, in the case that the value of the blast-radius configuration BRC is two and the quantity of rows to be refreshed is four, the refresh circuit can generate four pump signals; in the case that the value of the blast-radius configuration BRC is three and the quantity of rows to be refreshed is six, the refresh circuit can generate six pump signals; and in the case that the value of the blast-radius configuration BRC is four and the quantity of rows to be refreshed is eight, the refresh circuit can generate eight pump signals, and so on. Illustratively, referring to FIG. 10A, the pump signal DRFMpbPump may be an active-high square wave signal (pulse signal).

In some embodiments, the blast-radius configuration BRC may be defined by three data bits. That is, the blast-radius configuration BRC may be denoted as BRC<2:0>. In some embodiments, the blast-radius configuration includes different mark signals. The mark signals characterize whether the blast-radius configuration is supported by the refresh circuit and which type of the blast-radius configuration is supported. For example, a first mark signal BRC2 characterizes that the blast-radius configuration is supported by the refresh circuit and the supported type of the blast-radius configuration is 2. The refresh signal is a pulse signal received by the refresh circuit for indicating to start refreshing. The refresh signal may be active-high. For the refresh signal, reference may be made to DRFMpb in FIG. 10A. It can be understood that, in other embodiments, the blast-radius configuration may alternatively be defined by data bits less than three bits or greater than three bits, which is not limited herein.

As shown in FIG. 2, the feedback control circuit 21 is connected to the first operation circuit 22, and the first operation circuit 22 generates the pump signal DRFMpbPump in the case that the refresh signal DRFMpb or the pump trigger signal DRFMpbPumpTrig is in the enabled state. In some embodiments, the first pump signal DRFMpbPump is generated by using the refresh signal DRFMpb; and a remaining plurality of pump signals DRFMpbPump are all generated by using a plurality of corresponding pump trigger signals DRFMpbPumpTrig. Illustratively, referring to FIG. 10A, the pump trigger signal DRFMpbPumpTrig may be an active-high pulse signal.

Here, the feedback control circuit 21 is mainly configured to: generate the pump trigger signal, and terminate the generation of the pump trigger signal in the case that a quantity of pump signals expected to be generated meets a requirement of the blast-radius configuration, or a quantity of pump signals expected to be generated meets a requirement on a quantity of to-be-refreshed rows characterized by the blast-radius configuration. Here, in the case that the quantity of to-be-refreshed rows characterized by the blast-radius configuration BRC is N, that is, the quantity of to-be-refreshed rows (here, the quantity of rows may also be understood as a quantity of word lines) required for the blast-radius configuration BRC is N (N is an integer greater than two), N pump signals need to be generated. As the first pump signal is generated by using the refresh signal in advance, only N−1 pump trigger signals need to be generated for the remaining N−1 pump signals. Based on this, the quantity expected to be generated meets the requirement of the blast-radius configuration, which can be understood as in the case that the quantity of pump trigger signals is equal to N−1, the quantity of pump signals expected to be generated N meets the requirement on the quantity of to-be-refreshed rows N characterized by the blast-radius configuration. That is, in the case that the quantity of pump trigger signals is equal to N−1, the generation of the pump trigger signal is terminated.

Here, the rising edge of the pump delay signal RasPdlyR is delayed relative to that of the pump signal DRFMpbPump by the first preset duration. The first preset duration is greater than or equal to a time length for refreshing one word line. In some embodiments, the first preset duration is equal to the time length for refreshing one word line. Illustratively, the first preset duration is 42 nanoseconds (ns).

In some embodiments, as shown in FIG. 3, the feedback control circuit 21 includes:
an enable circuit 211, configured to: receive the pump delay signal and the blast-radius configuration, generate a first enable signal before the quantity of pump signals expected to be generated is equal to a quantity of to-be-refreshed rows characterized by the blast-radius configuration, and disable the first enable signal after the quantity of pump signals expected to be generated is equal to the quantity of to-be-refreshed rows characterized by the blast-radius configuration; and
a second operation circuit 212, configured to: receive the pump delay signal and the first enable signal, and generate the pump trigger signal based on the pump delay signal in the case that the first enable signal is received, where a moment at which the pump trigger signal is generated based on the same pump delay signal is prior to a moment at which the first enable signal is disabled.

Here, the enable circuit 211 is connected to the second operation circuit 212, and the first enable signal BRCEn generated based on the enable signal is used to indicate when the generation of the pump trigger signal is terminated. Illustratively, referring to FIG. 10A, the first enable signal BRCEn may be an active-high square wave signal and is pulled to a low level when the first enable signal is disabled. As mentioned above, in the case that the quantity of to-be-refreshed rows required for the blast-radius configuration BRC is N, that is, N pump signals need to be generated. As the first pump signal is generated by using the refresh signal in advance, N−1 pump trigger signals need to be generated. In other words, the quantity of pump signals expected to be generated is one more than the quantity of pump trigger signals.

It should be noted that, in terms of the time sequence, the moment at which the first enable signal BRCEn is disabled is ensured to be later than the moment at which the pump trigger signal DRFMpbPumpTrig is generated, such that the last pump trigger signal DRFMpbPumpTrig can be ensured to be successfully generated. With the time sequence ensured, the quantity of to-be-refreshed rows required for the blast-radius configuration BRC is N, and in the case that the quantity of pump trigger signals is N−1, the first enable signal needs to be disabled in time.

In some embodiments, as shown in FIG. 4, the enable circuit 21 includes: a first pulse generation circuit 211a, a first counter 211c, a mask circuit 211b, and a first comparison circuit 211d.

The first pulse generation circuit 211a is configured to: receive the pump delay signal, and generate a first pulse signal based on a falling edge of the pump delay signal.

The mask circuit 211b is coupled to the first pulse generation circuit 211a and configured to: receive the first pulse signal, block even-numbered first pulse signals, and output the remaining first pulse signal.

The first counter 211c is coupled to the mask circuit 211b and configured to: count a quantity of pulses in the remaining first pulse signals, and output a first counting signal.

The first comparison circuit 211d is coupled to the first counter 211c and configured to: receive the first counting signal and the blast-radius configuration, compare the first counting signal with the blast-radius configuration, and output the first enable signal in the case that the quantity of remaining pulses characterized by the first counting signal is less than half of the quantity of to-be-refreshed rows characterized by the blast-radius configuration; or disable the first enable signal in the case that the quantity of remaining pulses characterized by the first counting signal is equal to half of the quantity of to-be-refreshed rows characterized by the blast-radius configuration.

Here, the first pulse generation circuit 211a is connected to the mask circuit 211b, the mask circuit 211b is connected to both the first pulse generation circuit 211a and the first counter 211c, the first counter 211c is connected to the mask circuit 211b and the first comparison circuit 211d, and the first comparison circuit 211d is connected to the first counter 211c and the second operation circuit 212.

It can be understood that, in the case that the quantity of to-be-refreshed rows N required for the blast-radius configuration BRC is an even number, N−1 is an odd number. Based on this, the mask circuit herein blocks an even-numbered first pulse signal and outputs an odd-numbered first pulse signal, then counts up all output odd-numbered first pulse signals. In the case that a counted-up quantity is less than half of N required for the blast-radius configuration, it indicates that more pump trigger signals need to be generated, and in this case, the first enable signal is output; and in the case that the counted-up quantity is equal to half of N required for the blast-radius configuration, it indicates that no more pump trigger signals need not be generated, and in this case, the first enable signal is disabled.

Here, as shown in FIG. 5A, the first pulse generation circuit 211a may generate a first pulse signal based on a falling edge of the pump delay signal. In the first pulse generation circuit 211a, one end of a NOR gate receives the pump delay signal, and another end is connected to an output terminal of a delay unit. The pump delay signal first passes through an inverter and then the delay unit.

Here, as shown in FIG. 5B, the mask circuit 211b may be a circuit capable of extracting an odd-numbered pulse signal. Illustratively, for the odd-numbered pulse signal output by the mask circuit 211b, reference may be made to Pum1Clk in FIG. 10A.

Here, as shown in FIG. 5C, the first counter 211c may be a binary counter configured to: count a quantity of odd-numbered pulse signals output by the mask circuit 211b, obtain a binary counting result Pump1End<1:0> (Pump1EndN<1:0> and Pump1End<1:0> are inversion signals), and transmit the obtained binary counting result to the first comparison circuit. Illustratively, in the case that the quantity of input odd-numbered pulse signals is one, the first counter 211c outputs Pump1End<1> and Pump1End<0> as “0, 1”; in the case that the quantity of input odd-numbered pulse signals is two, the first counter 211c outputs Pump1End<1> and Pump1End<0> as “1, 0”; in the case that the quantity of input odd-numbered pulse signals is three, the first counter 211c outputs Pump1End<1> and Pump1End<0> as “1, 1”; and in the case that the quantity of input odd-numbered pulse signals is four, the first counter 211c outputs Pump1End<1> and Pump1End<0> as “0, 0”. In the case that the quantity of input odd-numbered pulse signals continues to increase, the first counter 211c starts counting from “0, 1” again.

In some embodiments, as shown in FIG. 5D, the first comparison circuit 211d includes: an AND circuit 211d-1 and a plurality of NAND gates 211d-2.

A plurality of input terminals of each NAND gate 211d-2 are each configured to receive a plurality of data bit signals included in the first counting signal and different mark signals. The mark signals characterize whether the blast-radius configuration is supported by the refresh circuit and which type of the blast-radius configuration is supported.

Input terminals of the AND circuit 211d-1 are each connected to an output terminal of each of the NAND gates 211d-2, and an output terminal of the AND circuit 211d-1 is configured to output the first enable signal or disable the first enable signal.

Here, the AND circuit 211d-1 may be understood as any circuit functioning equivalently to AND logic, for example, a series combination circuit including an AND gate, a NAND gate, and a NOT gate; or the like. The AND circuit 211d-1 shown in FIG. 5D is a series combination circuit including a NAND gate and a NOT gate.

In some embodiments, the mark signals include a first mark signal BRC2, a second mark signal BRC3, and a third mark signal BRC4. Here, the first mark signal BRC2 indicates that the blast-radius configuration is supported by the refresh circuit and the supported blast-radius configuration is two, and in this case, half of the quantity of to-be-refreshed rows indicated by the blast-radius configuration is two; the second mark signal BRC3 indicates that the blast-radius configuration is supported by the refresh circuit and the supported blast-radius configuration is three, and in this case, half of the quantity of to-be-refreshed rows characterized by the blast-radius configuration is three; and the third mark signal BRC4 indicates that the blast-radius configuration is supported by the refresh circuit and the supported blast-radius configuration is four, and in this case, half of the quantity of to-be-refreshed rows characterized by the blast-radius configuration is four.

A principle of forming a waveform of the first enable signal BRCEn is described below with reference to FIG. 5D and FIG. 10A.

Referring to FIG. 5D, take the quantity of to-be-refreshed rows N characterized by the blast-radius configuration being four as an example, in the case that the quantity of to-be-refreshed rows N characterized by the blast-radius configuration is four, the first mark signal BRC2 is enabled and is at a high level of “1”, and the second mark signal BRC3 and the third mark signal BRC4 are not enabled and are at a low level of “0”. In this case, outputs of NAND gate branches at which the second mark signal BRC3 and the third mark signal BRC4 are located are all at a high level of “1” regardless of an output of the first counter 211c. In the case that the quantity of input odd-numbered pulse signals is one, the first counter 211c outputs Pump1End<1> and Pump1End<0> as “0, 1”, three inputs of a NAND gate branch at which the first mark signal BRC2 is located are: “0, 0, 1”, and an output of the NAND gate branch at which the first mark signal BRC2 is located is 1. In this case, output signals BRCEnd of the three NAND gate branches with the effect of the AND circuit 211d-1 are at a high level. In the case that the quantity of input odd-numbered pulse signals is two, the first counter 211c outputs Pump1End<1> and Pump1End<0> as “1, 0”, three inputs of a NAND gate branch at which the first mark signal BRC2 is located are: “1, 1, 1”, and an output of the NAND gate branch at which the first mark signal BRC2 is located is 0. In this case, output signals BRCEnd of the three NAND gate branches with the effect of the AND circuit 211d-1 are at a low level. That is, as shown in FIG. 10A, the first enable signal BRCEn with 4pump changes from a high level to a low level after the second count of Pum1Clk.

It can be understood that, for a case that the quantity of to-be-refreshed rows N characterized by the blast-radius configuration is six or eight, reference may be made to the analysis provided above.

It should be noted that, the signal BRCEnd may be referred to as a first intermediate enable signal, and the first intermediate enable signal BRCEnd is used as a final first enable signal BRCEn in the case that no other signals for consideration, such as one characterizing whether the refresh circuit supports the blast-radius configuration setting and the second enable signal, are introduced.

In some embodiments, as shown in FIG. 4, the second operation circuit 212 includes: a third pulse generation circuit 212a, a first delay circuit 212b, and a third NAND gate 212c.

The third pulse generation circuit 212a is configured to: receive the pump delay signal, and generate a third pulse signal based on a falling edge of the pump delay signal.

The first delay circuit 212b is configured to delay a falling edge of the third pulse signal by a second preset duration, to obtain a pulse delay signal; the second preset duration is greater than or equal to a time length for pre-charging one row.

Two input terminals of the third NAND gate 212c are configured to receive the first enable signal and the pulse delay signal respectively, and an output terminal is configured to output the pump trigger signal.

Here, the third pulse generation circuit 212a and the foregoing first pulse generation circuit 211a both generate a corresponding pulse signal based on the falling edge of the pump delay signal. Based on this, the third pulse generation circuit 212a and the first pulse generation circuit 211a may be combined, and it can be understood that the two circuits may be separated as required. As shown in FIG. 4, the third pulse circuit 212a is combined with the first pulse generation circuit 211a.

Here, the second preset duration is greater than or equal to a time length for pre-charging one word line. In some embodiments, the second preset duration is equal to a time length for pre-charging one word line. Illustratively, the second preset duration is 18 ns.

A process of generating the pump trigger signal DRFMpbPumpTrig is described in detail below with reference to FIG. 10B.

A rising edge of the first pump signal DRFMpbPump is generated by using the refresh signal DRFMpb; the rising edge of the first pump signal DRFMpbPump is delayed by the first preset duration T1, to obtain a rising edge of the first pump delay signal RasPdlyR corresponding to the first pump signal; a falling edge of the first pump signal DRFMpbPump is obtained based on the rising edge of the first pump delay signal RasPdlyR; a falling edge of the first pump delay signal RasPdlyR is obtained based on the falling edge of the first pump signal DRFMpbPump; and the falling edge of the first pump delay signal RasPdlyR is delayed by the second preset duration T2, to obtain the first pump trigger signal DRFMpbPumpTrig.

A rising edge of the second pump signal DRFMpbPump is generated by using the pump trigger signal DRFMpbPumpTrig; the rising edge of the second pump signal DRFMpbPump is delayed by the first preset duration T1, to obtain a rising edge of the second pump delay signal RasPdlyR corresponding to the second pump signal; a falling edge of the second pump signal DRFMpbPump is obtained based on the rising edge of the second pump delay signal RasPdlyR; a falling edge of the second pump delay signal RasPdlyR is obtained based on the falling edge of the second pump signal DRFMpbPump; and the falling edge of the second pump delay signal RasPdlyR is delayed by the second preset duration T2, to obtain the second pump trigger signal DRFMpbPumpTrig.

The same logic goes on until rising edges and falling edges of the (N−1)^{th} pump trigger signal DRFMpbPumpTrig and the N^{th} pump signal DRFMpbPump are formed.

It should be noted that, as shown in FIG. 10B, the refresh signal DRFMpb and the rising edge of the first pump signal DRFMpbPump are not perfectly aligned, the rising edge of the first pump delay signal RasPdlyR and the falling edge of the first pump signal DRFMpbPump are not perfectly aligned; and the falling edge of the first pump signal DRFMpbPump and the falling edge of the first pump delay signal RasPdlyR are not perfectly aligned, but there are delays caused by a device itself.

In some embodiments, as shown in FIG. 6, the first operation circuit 22 includes: a NOR circuit 221, a second delay circuit 222, a fourth NAND gate 223, a fifth NAND gate 224, and a second NOT gate 225.

Input terminals of the NOR circuit 221 are configured to receive the refresh signal and the pump trigger signal respectively.

One input terminal of the fourth NAND gate 223 is connected to an output terminal of the NOR circuit 221, another input terminal is connected to an output terminal of the fifth NAND gate 224, and an output terminal is configured to output the pump signal.

One input terminal of the fifth NAND gate 224 is connected to the output terminal of the fourth NAND gate 223, and another input terminal is connected to an output terminal of the second NOT gate 225.

An input terminal of the second NOT gate 225 is configured to receive the pump delay signal.

An input terminal of the second delay circuit 222 is configured to receive the pump signal, an output terminal is configured to output the pump delay signal, and the second delay circuit 222 is configured to delay a rising edge of the pump signal by a first preset duration; the first preset duration is greater than or equal to a time length for refreshing one row.

Here, the NOR circuit 221 may be understood as any circuit functioning equivalently to NOR logic, for example, a series combination circuit including a NOR gate, an OR gate, and a NOT gate, a combination circuit including a NAND gate and a plurality of NOT gates, or the like. As shown in FIG. 6, the NOR circuit 221 is a combination circuit including a NAND gate and a plurality of NOT gates, in which two input terminals and one output terminal of the NAND gate are each connected in series to one of the NOT gates.

Generally, the first enable signal is generated before the quantity of pump signals expected to be generated is equal to the quantity of to-be-refreshed rows characterized by the blast-radius configuration. In this case, the pump trigger signal may be generated, such that the pump signal is generated. The first enable signal is disabled at an appropriate time when the quantity of pump signals expected to be generated is equal to the quantity of to-be-refreshed rows characterized by the blast-radius configuration, such that the generation of the pump trigger signal is terminated in time, and a quantity of generated pump signals meets a requirement of the blast-radius configuration. However, if a glitch or another special issue appears in the refresh circuit, the second enable signal may be used for time domain limitation, such that the first enable signal can only take effect in a valid range specified by the second enable signal, to improve the reliability of the refresh circuit provided in the embodiments of the present disclosure.

In some embodiments, as shown in FIG. 7, the refresh circuit 20 further includes a boundary circuit 23, configured to: receive a refresh signal and a refresh-off signal, and generate a second enable signal based on the refresh signal and the refresh-off signal. The enabling duration of the second enable signal begins upon receiving the refresh signal and ends when the refresh-off signal switches to an active state; the switching to the active state by the refresh-off signal characterizes that the quantity of generated pump signals is equal to the quantity of to-be-refreshed rows characterized by the blast-radius configuration; and
the first comparison circuit 211d is coupled to the boundary circuit 23 and further configured to: receive the second enable signal, and disable the first enable signal in the case that the second enable signal is in a sleep state.

Here, the boundary circuit 23 is connected to the enable circuit 211, and the boundary circuit 23 generates the second enable signal DRFMIP based on the refresh signal DRFMpb and the refresh-off signal DRFMoff. Illustratively, referring to FIG. 10A, a rising edge of the second enable signal DRFMIP is aligned with the refresh signal DRFMpb, a falling edge of the second enable signal DRFMIP is aligned with a falling edge of the refresh-off signal DRFMoff, a high level of the second enable signal DRFMIP is a sleep state, and a low level of DRFMIP is an active state. In the case that the second enable signal DRFMIP switches from the high level to the low level, it characterizes that the quantity of generated pump signals is equal to the quantity of to-be-refreshed rows characterized by the blast-radius configuration.

Further referring to FIG. 5D, the first comparison circuit 211d may further include one AND circuit 211d-3. The AND circuit 211d-3 may also be understood as any circuit functioning equivalently to AND logic. The AND circuit 211d-3 shown in FIG. 5D is a series combination circuit of a NAND gate and a NOT gate. Based on the previously obtained first intermediate enable signal BRCEnd, the second enable signal DRFMIP may be further introduced, and the falling edge of the second enable signal DRFMIP is aligned with the falling edge of the refresh-off signal DRFMoff. After the falling edge of the second enable signal DRFMIP, the second enable signal DRFMIP is in the sleep state, and in the case that the second enable signal DRFMIP is in the sleep state, the first enable signal is disabled. In this case, with the support of the second enable signal, the first enable signal may be more stable, such that the refresh circuit is not affected due to the first enable signal with a glitch, thereby improving the reliability of the refresh circuit.

In addition, it can be understood that, based on the first intermediate enable signal BRCEnd, the refresh circuit may generate the corresponding first enable signal BRCEn on the premise that the blast-radius configuration function is supported (corresponding to a high level of “1” of BRCsupport in FIG. 5D).

In some embodiments, as shown in FIG. 7, the boundary circuit 23 includes:
a refresh-off circuit 231, configured to receive the pump signal and the blast-radius configuration, where the refresh-off signal enters the sleep state in the case that the quantity of pump signals is close to the quantity of to-be-refreshed rows characterized by the blast-radius configuration, and the refresh-off signal switches to the active state in the case that the quantity of pump signals is equal to the quantity of to-be-refreshed rows characterized by the blast-radius configuration; and
a third operation circuit 232, configured to: receive the refresh signal and the refresh-off signal, perform a logic operation on the refresh signal and the refresh-off signal, and generate the second enable signal after the reception of the refresh signal and before the refresh-off signal switches to the active state.

Here, the quantity of pump signals is close to the blast-radius configuration, which may be understood as the quantity of pump signals being less than the quantity of to-be-refreshed rows characterized by the blast-radius configuration. Illustratively, in the case that the quantity of to-be-refreshed rows characterized by the blast-radius configuration is four, the quantity of pump signals that is close to the blast-radius configuration may be two; in the case that the quantity of to-be-refreshed rows characterized by the blast-radius configuration is six, the quantity of pump signals that is close to the blast-radius configuration may be four; and in the case that the quantity of to-be-refreshed rows characterized by the blast-radius configuration is eight, the quantity of pump signals that is close to the blast-radius configuration may be six. It can be understood that being close herein may be adjusted based on actual requirements.

Here, the falling edge of the refresh-off signal DRFMoff is used to provide a reference for the second enable signal DRFMIP. Illustratively, referring to FIG. 10A, the falling edge of the refresh-off signal DRFMoff is aligned with a falling edge of the last pump signal DRFMpbPump, a high level of the refresh-off signal DRFMIP is a sleep state, and a low level of the refresh-off signal DRFMIP is an active state. In the case that the quantity of pump signals is equal to the quantity of to-be-refreshed rows characterized by the blast-radius configuration, the refresh-off signal DRFMIP switches from the sleep state to the active state, that is, switches from the high level to the low level.

It should be noted that, a moment at which the refresh-off signal DRFMoff switches to the active state is fixed, but a moment at which the refresh-off signal enters the sleep state may be adjusted based on actual situations. Illustratively, in the case that the quantity of to-be-refreshed rows characterized by the blast-radius configuration is four, the refresh-off signal DRFMoff may enter the sleep state from two, or enter the sleep state from three; in the case that the quantity of to-be-refreshed rows characterized by the blast-radius configuration is six, the refresh-off signal DRFMoff may enter the sleep state from four, or enter the sleep state from five; and in the case that the quantity of to-be-refreshed rows characterized by the blast-radius configuration is eight, the refresh-off signal DRFMoff may enter the sleep state from four, or enter the sleep state from any one of five to seven.

In some embodiments, as shown in FIG. 8, the refresh-off circuit 231 includes: a clock generation circuit 231a, a second counter 231b, and a second comparison circuit 231c.

The clock generation circuit 231a is configured to: receive the pump signal, and generate a clock signal based on the pump signal.

The second counter 231b is coupled to the clock generation circuit and configured to: count a quantity of pulses in the clock signal and output a second counting signal. The second counting signal includes a multi-bit binary counting signal.

The second comparison circuit 231c is coupled to the second counter and configured to: receive the second counting signal and the blast-radius configuration, and compare the second counting signal with the blast-radius configuration, where the refresh-off signal enters the sleep state during a period from the start of the flip of a counting signal on a corresponding bit in the second counting signal to a first state until a next flip occurs, and in the case that the next flip after the first state occurs, a quantity of second counting signals is equal to the quantity of to-be-refreshed rows characterized by the blast-radius configuration; and the refresh-off signal switches to the active state after the next flip of the counting signal on the corresponding bit in the second counting signal occurs.

Here, the clock generation circuit 231a is connected to the second counter 231b, the second counter 231b is connected to both the clock generation circuit 231a and the second comparison circuit 231c, and the second comparison circuit 231c is connected to the second counter 231b and the third operation circuit 232.

Here, as shown in FIG. 9A, the clock generation circuit 231a may generate a clock signal based on the pump signal. The clock signal herein may be a pair of clock signals ClkN and Clk that are inversion signals.

Here, the second counter 231b may be a three-bit eight-state counter with a circuit composition and a connection manner similar to those of a frequency dividing circuit. As shown in FIG. 9B, a data output terminal of each of three flip-flops is connected to its own data input terminal by using one inverter, and is connected to a clock input terminal of a next flip-flop by using another inverter. Each of the flip-flops is connected to a corresponding reset signal.

The second counter 231b may be configured to: count a quantity of pulses in the clock signal generated based on the pump signal, to obtain counting results: a third counting mark Cnt2, a second counting mark Cnt4, and a first counting mark Cnt8 (a signal CntN4 and the second counting mark Cnt4 are inversion signals), and transmit the obtained counting results to the second comparison circuit. Illustratively, in the case that the quantity of input pulses is one, the first counting mark Cnt8, the second counting mark Cnt4, and the third counting mark Cnt2 on three bits output by the second counter 231b are “0, 0, 1” from high to low respectively; in the case that the quantity of input pulses is two, the first counting mark Cnt8, the second counting mark Cnt4, and the third counting mark Cnt2 on three bits output by the second counter 231b are “0, 1, 0” from high to low respectively; in the case that the quantity of input pulses is three, the first counting mark Cnt8, the second counting mark Cnt4, and the third counting mark Cnt2 on three bits output by the second counter 231b are “0, 1, 1” from high to low respectively; in the case that the quantity of input pulses is four, the first counting mark Cnt8, the second counting mark Cnt4, and the third counting mark Cnt2 on three bits output by the second counter 231b are “1, 0, 0” from high to low respectively; in the case that the quantity of input pulses is five, the first counting mark Cnt8, the second counting mark Cnt4, and the third counting mark Cnt2 on three bits output by the second counter 231b are “1, 0, 1” from high to low respectively; in the case that the quantity of input pulses is six, the first counting mark Cnt8, the second counting mark Cnt4, and the third counting mark Cnt2 on three bits output by the second counter 231b are “1, 1, 0” from high to low respectively; in the case that the quantity of input pulses is seven, the first counting mark Cnt8, the second counting mark Cnt4, and the third counting mark Cnt2 on three bits output by the second counter 231b are “1, 1, 1” from high to low respectively; and in the case that the quantity of input pulses is eight, the first counting mark Cnt8, the second counting mark Cnt4, and the third counting mark Cnt2 on three bits output by the second counter 231b are “0, 0, 0” from high to low respectively. In the case that a quantity of pulses continues to increase, the second counter 231b starts from 001 again.

Here, the mark signals BRC2, BRC3, and BRC4 have the same meaning as the foregoing mark signals BRC2, BRC3, and BRC4. Details are not provided herein again. The second comparison circuit 231c is relatively similar to the foregoing first comparison circuit 211d in terms of an implementing principle.

A principle of forming a waveform of the refresh-off signal DRFMoff is described below with reference to FIG. 9B, FIG. 9C, and FIG. 10A.

Referring to FIG. 9C, take the quantity of to-be-refreshed rows N characterized by the blast-radius configuration being four as an example, in the case that the quantity of to-be-refreshed rows N characterized by the blast-radius configuration is four, the first mark signal BRC2 is enabled and is at a high level of “1”, and the second mark signal BRC3, the third mark signal BRC4, and a status mark signal BRCDis are not enabled and are at a low level of “0”. In this case, outputs of NAND gate branches at which the second mark signal BRC3, the third mark signal BRC4, and the status mark signal BRCDis are located are all at a high level of “1” regardless of an output of the second counter 231b. In the case that the quantity of input pulses is two, the first counting mark Cnt8, the second counting mark Cnt4, and the third counting mark Cnt2 on three bits output by the second counter 231b are “0, 1, 0” from high to low respectively; two inputs, that is, the second counting mark Cnt4 and the first mark signal BRC2, of the NAND gate branch at which the first mark signal BRC2 is located are “1, 1”; and an output of the NAND gate branch at which the first mark signal BRC2 is located is 0. In this case, the signal DRFMoff output by the four NAND gate branches through the comprehensive effect of the NAND gate is at a high level of “1”. That is, the refresh-off signal DRFMoff can enter the sleep state from two. In the case that the quantity of input pulses is four, the first counting mark Cnt8, the second counting mark Cnt4, and the third counting mark Cnt2 on three bits output by the second counter 231b are “1, 0, 0” from high to low respectively; the two inputs, that is, the second counting mark Cnt4 and the first mark signal BRC2, of the NAND gate branch at which the first mark signal BRC2 is located are “0, 1”; and the output of the NAND gate branch at which the first mark signal BRC2 is located is 1. In this case, the signal DRFMoff output by the four NAND gate branches through the comprehensive effect of the NAND gate is at a low level of “0”. That is, the refresh-off signal DRFMoff switches to the active state from four.

Take the quantity of to-be-refreshed rows N characterized by the blast-radius configuration being six as another example, in the case that the quantity of to-be-refreshed rows N characterized by the blast-radius configuration is six, the second mark signal BRC3 is enabled and is at a high level of “1”; and the first mark signal BRC2, the third mark signal BRC4, and the status mark signal BRCDis are not enabled and are at a low level of “0”. In this case, outputs of NAND gate branches at which the first mark signal BRC2, the third mark signal BRC4, and the status mark signal BRCDis are located are all at a high level of “1” regardless of an output of the second counter 231b. In the case that the quantity of input pulses is four, the first counting mark Cnt8, the second counting mark Cnt4, and the third counting mark Cnt2 on three bits output by the second counter 231b are “1, 0, 0” from high to low respectively; three inputs, that is, the first counting mark Cnt8, CntN4, and the second mark signal BRC3, of the NAND gate branch at which the second mark signal BRC3 is located are “1, 1, 1”; and an output of the NAND gate branch at which the second mark signal BRC3 is located is 0. In this case, the signal DRFMoff output by the four NAND gate branches through the comprehensive effect of the NAND gate is at a high level of “1”. That is, the refresh-off signal DRFMoff can enter the sleep state from four. In the case that the quantity of input pulses is six, the first counting mark Cnt8, the second counting mark Cnt4, and the third counting mark Cnt2 on three bits output by the second counter 231b are “1, 1, 0” from high to low respectively; the three inputs, that is, the first counting mark Cnt8, CntN4, and the second mark signal BRC3, of the NAND gate branch at which the second mark signal BRC3 is located are “1, 0, 1”; and the output of the NAND gate branch at which the second mark signal BRC3 is located is 1. In this case, the signal DRFMoff output by the four NAND gate branches through the comprehensive effect of the NAND gate is at a low level of “0”. That is, the refresh-off signal DRFMoff switches to the active state from six.

It can be understood that, for a case that the quantity of to-be-refreshed rows N characterized by the blast-radius configuration is eight, reference may be made to the analysis provided above with N being four.

In some embodiments, as shown in FIG. 8, the third operation circuit 232 includes: a second pulse generation circuit 232a, a first NOT gate 232b, a first NAND gate 232c, and a second NAND gate 232d.

An input terminal of the second pulse generation circuit 232a is configured to: receive the refresh-off signal, and generate a second pulse signal based on a falling edge of the refresh-off signal.

An input terminal of the first NOT gate 232b is configured to receive the refresh signal.

One input terminal of the first NAND gate 232c is connected to an output terminal of the second pulse generation circuit 232a, and another input terminal is connected to an output terminal of the second NAND gate 232d.

One input terminal of the second NAND gate 232d is connected to an output terminal of the first NOT gate 232b, another input terminal is connected to an output terminal of the first NAND gate 232c, and an output terminal of the second NAND gate 232d is configured to output the second enable signal.

Here, the second pulse generation circuit 232a may generate a second pulse signal based on the falling edge of the refresh-off signal. Illustratively, for the second pulse signal, reference may be made to DRFMoffClk in FIG. 10A.

Here, the first NOT gate 232b, the first NAND gate 232c, and the second NAND gate 232d may function equivalently to one latch. The rising edge of the second enable signal DRFMIP is aligned with the refresh signal DRFMpb, and the falling edge of the second enable signal DRFMIP is aligned with the second pulse signal DRFMoffClk.

The refresh circuit provided in the embodiments of the present disclosure can terminate the pump trigger signal in time, and thus generate pump signals of which the quantity meets the requirement of the blast-radius configuration, thereby achieving multi-pump refresh that is consistent with a quantity of to-be-refreshed rows characterized by the blast-radius configuration.

An embodiment of the present disclosure further provides a memory. The memory includes:
a plurality of memory banks; and
a refresh management circuit, coupled to the plurality of memory banks and including the refresh circuit provided in the foregoing embodiments of the present disclosure.

In some embodiments, the memory includes a dynamic random access memory.

FIG. 11 is a schematic diagram of a memory according to an embodiment of the present disclosure.

As shown in FIG. 11, the memory 10 includes: a memory array 100, a register 101, a refresh management circuit 102, a command decoder 103, an address buffer 104, a counter 105, a row address multiplexer 106, a plurality of row decoders 107, a memory bank control logic 108, a column address latch 109, a plurality of column decoders 110, an input/output gating circuit 111, and a data input/output buffer 112.

In some specific embodiments, the memory array 100 may include a plurality of memory banks, and a plurality of sense amplifiers separately corresponding to the plurality of memory banks. Here, each of the plurality of memory banks includes a plurality of row addresses; and each of the plurality of row addresses is connected to one corresponding word line.

In some specific embodiments, the address buffer 104 may be configured to receive a row address or a column address of the memory array. The address buffer 104 may send the row address to the row decoders 107, and may send the column address to the column decoders 110. The row decoders 107 select at least one of a plurality of word lines connected to the memory bank based on the row address received from the address buffer 104, and the row decoders 107 activate the selected word line in response to a control signal. The column decoders 110 select at least one of a plurality of bit lines connected to the memory array, and the column decoders 110 activate the selected bit line in response to a control signal. Here, each of the memory banks includes a plurality of memory cells connected to word lines and bit lines. The sense amplifier senses a voltage change of an activated bit line among the bit lines, and amplifies the voltage change to generate output data. The data input/output buffer 112 outputs the data to an external device, for example, a memory controller, through a data line based on a voltage amplified by the sense amplifier.

In some specific embodiments, the command decoder 103 may receive an address ADDR provided by the memory controller. The address ADDR may include a memory bank address BA. In addition, the address ADDR may include a row address ROW_ADDR for indicating a row in the memory array and a column address COL_ADDR for indicating a column in the memory array. The row address ROW_ADDR may be provided to the plurality of row decoders 107 by a row address selector, and the column address COL_ADDR may be provided to the plurality of column decoders 110 by a column address latch. In addition, the memory bank address BA may be provided to the memory bank control logic 108. The memory bank control logic 108 may generate a memory bank control signal in response to the memory bank address BA. Further, in response to the memory bank control signal, a row decoder 107 corresponding to the memory bank address BA among the plurality of row decoders 107 may be activated, and a column decoder 110 corresponding to the memory bank address BA among the plurality of column decoders may be activated.

It should be noted that, various components of the memory 10 shown in FIG. 11 are merely for illustrating an operating principle of the memory 10 and an operating environment of the refresh management circuit 12 at which the refresh circuit is located more clearly, but are not for limiting a composition structure of the memory 10.

It should be noted that, according to the embodiments of the present disclosure, different refreshing times with different pumps can be achieved based on different BRCs, such that a refresh mode proposed in LP5 JEDEC SPEC can be achieved, and DRAM row hammer refresh performance (DRAM RHR performance) can be improved.

The foregoing description shows merely preferred embodiments of the present disclosure and is not intended to limit the protection scope of the present disclosure.

It should be noted that in the present disclosure, the terms “include”, “comprise”, or any other variants thereof are intended to cover non-exclusive inclusion, such that a process, a method, an item, or an apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The serial numbers of the embodiments of the present disclosure described above are for the purpose of describing only and do not represent the superiority or inferiority of the embodiments.

The methods disclosed in the method embodiments provided in the present disclosure may be combined in any manner without conflict to obtain new method embodiments.

The features disclosed in the product embodiments provided in the present disclosure may be combined in any manner without conflict to obtain new product embodiments.

The features disclosed in the method or device embodiments provided in the present disclosure may be combined in any manner without conflict to obtain new method or device embodiments.

The foregoing description is merely the specific embodiments of the present disclosure, but the protection scope of the present disclosure is not limited thereto; and changes or substitutions that any one skilled in the art can easily think of within the technical scope disclosed by the present disclosure shall all fall within the protection scope of the present disclosure.

What is claimed is:

1. A refresh circuit, comprising:
a feedback control circuit, configured to: receive a pump delay signal and a blast-radius configuration; generate a pump trigger signal based on the pump delay signal, the pump trigger signal being used to generate a pump signal, and each pump signal having a corresponding pump delay signal; and terminate generation of the pump trigger signal in a case that a quantity of pump signals expected to be generated meets a requirement of the blast-radius configuration, wherein the pump signal is used to perform a refresh operation; and
a first operation circuit, configured to: receive a refresh signal and the pump trigger signal, perform a logic operation on the refresh signal and the pump trigger signal, and generate the pump signal in a case that the refresh signal or the pump trigger signal is in an enabled state, wherein each pump signal is used to perform one refresh operation; a rising edge of the pump delay signal is delayed relative to a rising edge of the pump signal by a first preset duration.

2. The refresh circuit according to claim 1, wherein the feedback control circuit comprises:
an enable circuit, configured to: receive the pump delay signal and the blast-radius configuration, generate a first enable signal before the quantity of pump signals expected to be generated is equal to a quantity of to-be-refreshed rows characterized by the blast-radius configuration, and disable the first enable signal after the quantity of pump signals expected to be generated is equal to the quantity of to-be-refreshed rows characterized by the blast-radius configuration; and
a second operation circuit, configured to: receive the pump delay signal and the first enable signal, and generate the pump trigger signal based on the pump delay signal in a case that the first enable signal is received, wherein a moment at which the pump trigger signal is generated based on the same pump delay signal is prior to a moment at which the first enable signal is disabled.

3. The refresh circuit according to claim 2, wherein the enable circuit comprises: a first pulse generation circuit, a first counter, a mask circuit, and a first comparison circuit, wherein
the first pulse generation circuit is configured to: receive the pump delay signal and generate a first pulse signal based on a falling edge of the pump delay signal;
the mask circuit is coupled to the first pulse generation circuit and configured to: receive the first pulse signal, block even-numbered first pulse signals, and output remaining first pulse signals;
the first counter is coupled to the mask circuit and configured to: count a quantity of pulses in the remaining first pulse signals, and output a first counting signal; and
the first comparison circuit is coupled to the first counter and configured to: receive the first counting signal and the blast-radius configuration, compare the first counting signal with the blast-radius configuration, output the first enable signal in a case that the quantity of remaining pulses characterized by the first counting signal is less than half of the quantity of to-be-refreshed rows characterized by the blast-radius configuration, or disable the first enable signal in a case that the quantity of remaining pulses characterized by the first counting signal is equal to half of the quantity of to-be-refreshed rows characterized by the blast-radius configuration.

4. The refresh circuit according to claim 3, wherein the first comparison circuit comprises: an AND circuit and a plurality of NAND gates, wherein
a plurality of input terminals of each of the plurality of NAND gates are each configured to receive a plurality of data bit signals comprised in the first counting signal and different mark signals, and the mark signals characterize whether the blast-radius configuration is supported by the refresh circuit and which type of the blast-radius configuration is supported; and
input terminals of the AND circuit are each connected to an output terminal of each of the NAND gates, and an output terminal of the AND circuit is configured to output the first enable signal or disable the first enable signal.

5. The refresh circuit according to claim 3, further comprising: a boundary circuit, configured to: receive a refresh signal and a refresh-off signal and generate a second enable signal based on the refresh signal and the refresh-off signal, wherein an enabling duration of the second enable signal begins upon receiving the refresh signal and ends when the refresh-off signal switches to an active state; the switching to the active state by the refresh-off signal characterizes that a quantity of generated pump signals is equal to the quantity of to-be-refreshed rows characterized by the blast-radius configuration; and
the first comparison circuit is coupled to the boundary circuit and further configured to: receive the second enable signal and disable the first enable signal in a case that the second enable signal is in a sleep state.

6. The refresh circuit according to claim 5, wherein the boundary circuit comprises:
a refresh-off circuit, configured to receive the pump signal and the blast-radius configuration, wherein the refresh-off signal enters the sleep state in a case that the quantity of pump signals is close to the quantity of to-be-refreshed rows characterized by the blast-radius configuration, and the refresh-off signal switches to the active state in a case that the quantity of pump signals is equal to the quantity of to-be-refreshed rows characterized by the blast-radius configuration; and
a third operation circuit, configured to: receive the refresh signal and the refresh-off signal, perform a logic operation on the refresh signal and the refresh-off signal, and generate the second enable signal from a time the refresh signal is received until the refresh-off signal switches to the active state.

7. The refresh circuit according to claim 6, wherein the refresh-off circuit comprises: a clock generation circuit, a second counter, and a second comparison circuit, wherein
the clock generation circuit is configured to: receive the pump signal and generate a clock signal based on the pump signal;
the second counter is coupled to the clock generation circuit and configured to: count a quantity of pulses in the clock signal and output a second counting signal; the second counting signal comprises a multi-bit binary counting signal; and
the second comparison circuit is coupled to the second counter and configured to: receive the second counting signal and the blast-radius configuration and compare the second counting signal with the blast-radius configuration, wherein the refresh-off signal enters the sleep state during a period from a start of a flip of a counting signal on a corresponding bit in the second counting signal to a first state until a next flip occurs, and in a case that the next flip after the first state occurs, a quantity of second counting signals is equal to the quantity of to-be-refreshed rows characterized by the blast-radius configuration; the refresh-off signal switches to the active state after the next flip of the counting signal on the corresponding bit in the second counting signal occurs.

8. The refresh circuit according to claim 6, wherein the third operation circuit comprises: a second pulse generation circuit, a first NOT gate, a first NAND gate, and a second NAND gate, wherein
an input terminal of the second pulse generation circuit is configured to: receive the refresh-off signal and generate a second pulse signal based on a falling edge of the refresh-off signal;
an input terminal of the first NOT gate is configured to receive the refresh signal;
one input terminal of the first NAND gate is connected to an output terminal of the second pulse generation circuit, and another input terminal is connected to an output terminal of the second NAND gate; and
one input terminal of the second NAND gate is connected to an output terminal of the first NOT gate, another input terminal is connected to an output terminal of the first NAND gate, and an output terminal of the second NAND gate is configured to output the second enable signal.

9. The refresh circuit according to claim 2, wherein the second operation circuit comprises: a third pulse generation circuit, a first delay circuit, and a third NAND gate, wherein
the third pulse generation circuit is configured to: receive the pump delay signal and generate a third pulse signal based on a falling edge of the pump delay signal;
the first delay circuit is configured to: delay a falling edge of the third pulse signal by a second preset duration to obtain a pulse delay signal; the second preset duration is greater than or equal to a time length for pre-charging one row; and
two input terminals of the third NAND gate are configured to receive the first enable signal and the pulse delay signal respectively, and an output terminal is configured to output the pump trigger signal.

10. The refresh circuit according to claim 1, wherein the first operation circuit comprises: a NOR circuit, a second delay circuit, a fourth NAND gate, a fifth NAND gate, and a second NOT gate, wherein
input terminals of the NOR circuit are configured to receive the refresh signal and the pump trigger signal respectively;
one input terminal of the fourth NAND gate is connected to an output terminal of the NOR circuit, another input terminal is connected to an output terminal of the fifth NAND gate, and an output terminal is configured to output the pump signal;
one input terminal of the fifth NAND gate is connected to an output terminal of the fourth NAND gate, and another input terminal is connected to an output terminal of the second NOT gate;
an input terminal of the second NOT gate is configured to receive the pump delay signal; and
an input terminal of the second delay circuit is configured to receive the pump signal, an output terminal is configured to output the pump delay signal, and the second delay circuit is configured to delay a rising edge of the pump signal by a first preset duration; the first preset duration is greater than or equal to a time length for refreshing one row.

11. A memory, comprising:
a plurality of memory banks; and
a refresh management circuit, coupled to the plurality of memory banks and comprising a refresh circuit, the refresh circuit comprising:
a feedback control circuit, configured to: receive a pump delay signal and a blast-radius configuration; generate a pump trigger signal based on the pump delay signal, the pump trigger signal being used to generate a pump signal, and each pump signal having a corresponding pump delay signal; and terminate generation of the pump trigger signal in a case that a quantity of pump signals expected to be generated meets a requirement of the blast-radius configuration, wherein the pump signal is used to perform a refresh operation; and
a first operation circuit, configured to: receive a refresh signal and the pump trigger signal, perform a logic operation on the refresh signal and the pump trigger signal, and generate the pump signal in a case that the refresh signal or the pump trigger signal is in an enabled state, wherein each pump signal is used to perform one refresh operation; a rising edge of the pump delay signal is delayed relative to a rising edge of the pump signal by a first preset duration.

12. The memory according to claim 11, comprising a dynamic random access memory.
